(19) United States
(12) Patent Application Publication
(10) Pub. No.: US 2025/0351746 A1
(43) Pub. Date: Nov. 13, 2025

(54) NON-VOLATILE MEMORY UNIT CELL HAVING EDGE-CONTACTED MEMRISTIVE DEVICE

(71) Applicant: International Business Machines Corporation, Armonk, NY (US)

(72) Inventors: Ghazi Sarwat Syed, Zurich (CH); Vara Sudananda Prasad Jonnalagadda, Zurich (CH)

(21) Appl. No.: 18/660,328

(22) Filed: May 10, 2024

(51) Int. Cl. H10N 70/20; H10B 63/10; H10N 70/00

(52) U.S. Cl. CPC H10N 70/231; H10B 63/10; H10N 70/021; H10N 70/061; H10N 70/823; H10N 70/841

(57) ABSTRACT

Embodiments are disclosed for a semiconductor structure. The semiconductor structure includes a non-volatile memory unit cell. The non-volatile memory unit cell includes a top electrode in contact with a bit line. Additionally, the non-volatile memory unit cell includes a bottom electrode in contact with a select line. Further, the non-volatile memory unit cell includes a thin film electrode in contact with the bottom electrode. Additionally, the non-volatile memory unit cell includes a dielectric in contact with the top electrode and the thin film electrode. Further, the non-volatile memory unit cell includes a layer of phase change material including memristive channels. Additionally, the layer of phase change material is in contact with the dielectric. Further, the memristive channels are in contact with the top electrode, the thin film electrode, and the dielectric.

### BACKGROUND

The present disclosure generally relates to non-volatile memory unit cells, and more particularly to non-volatile memory unit cells having memristive devices.

Compute unit cells may be useful in non-volatile memories. Non-volatile memories are useful for data storage, as well as analog in-memory computing. Further, non-volatile memories include multiple random access memory cells (memory cells) that may include a phase change material arranged between, and coupled to, at least two electrodes. As such, when a non-volatile memory unit cell is in use, the phase change material may be configured in one of at least two reversibly transformable phases, an amorphous phase and a crystalline phase. The amorphous phase and the crystalline phase are distinct from one another. In the amorphous phase, the phase change material has a discernibly higher resistance in comparison to the crystalline phase. Further, in order to facilitate a phase transition, energy is supplied to the phase change material such as, electrical energy, thermal energy, any other suitable form of energy, or a combination that may cause the phase transition.

### SUMMARY

According to embodiments of the present disclosure, a non-volatile memory unit cell is provided. The non-volatile memory unit cell includes a top electrode in contact with a bit line. The non-volatile memory unit cell further includes a bottom electrode in contact with a select line. The non-volatile memory unit cell further includes a thin film electrode in contact with the bottom electrode. The non-volatile memory unit cell further includes a dielectric in contact with the top electrode and the thin film electrode. The non-volatile memory unit cell further includes a layer of phase change material including memristive channels. The layer of phase change material is in contact with the dielectric. The memristive channels are in contact with the top electrode, the thin film electrode, and the dielectric.

According to further embodiments of the present disclosure, a second non-volatile memory unit cell is provided. The non-volatile memory unit cell includes a first top electrode in contact with a first bit line. The non-volatile memory unit cell further includes a second top electrode in contact with a second bit line. A differential pair includes the first bit line and the second bit line. The non-volatile memory unit cell further includes a first diode in contact with the first top electrode. The non-volatile memory unit cell further includes a second diode in contact with the second top electrode. The non-volatile memory unit cell further includes a bottom electrode in contact with a select line. The non-volatile memory unit cell further includes a thin film electrode in contact with the bottom electrode. The non-volatile memory unit cell further includes a dielectric in contact with the first top electrode, the second top electrode, the first diode, the second diode, and the thin film electrode. The non-volatile memory unit cell further includes a layer of phase change material comprising a first memristive channel and a second memristive channel. The layer of phase change material is in contact with the dielectric. The first memristive channel is in contact with the thin film electrode, the first diode, and the dielectric. The second memristive channel is in contact with the thin film electrode, the second diode, and the dielectric.

According to further embodiments of the present disclosure, a method for fabricating a semiconductor structure is provided, the method includes performing patterning of a bottom electrode. The method further includes depositing a conductive thin film on the bottom electrode. The method further includes depositing a dielectric layer on the conductive thin film. The method further includes performing patterning of a non-volatile memory unit cell. The method further includes depositing a memristive film on the patterned non-volatile memory unit cell. The method further includes performing patterning of a first top electrode. The method further includes depositing the top electrode on the memristive film.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1 depicts example non-volatile memory unit cells having edge-contacted memristive channels, in accordance with some embodiments of the present disclosure.

FIG. 2 depicts example non-volatile memory unit cells having edge-contacted memristive channels and a differential pair, in accordance with some embodiments of the present disclosure.

FIG. 3A depicts internal cross-sectional views of example memristive devices having edge-contacted memristive channels, in accordance with some embodiments of the present disclosure.

FIG. 3B depicts internal cross-sectional views of example memristive devices having projected-type, edge-contacted memristive channels, in accordance with some embodiments of the present disclosure.

FIG. 4 depicts a process flow chart of a method for fabricating a compute unit cell having memristive devices with shared electrodes, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

Detailed embodiments of the claimed structures and methods are disclosed herein; however, it can be understood that the disclosed embodiments are merely illustrative of the claimed structures and methods that may be embodied in various forms. The disclosure may, however, be embodied in many different forms and should not be construed as limited to the example embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub lithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

Memristive devices, such as phase change memory cells are useful in analog computing applications. A memristive device (e.g., memristor) is a form of non-volatile memory having a resistor function that programs the resistance of the memory. Additionally, a memristive device can be switched between two or more resistance states. Further, memristive devices make up compute unit cells, such as non-volatile memory cells. For example, a compute unit cell may include two or more memristive devices. Further, a multi-memory cell architecture may include several mushroom-type phase change cells. However, while this architecture includes multiple phase change cells, such an architecture may represent one compute unit cell because the top electrode is shared and connected to a common bit line.

Additionally, this multi-memory cell architecture may include separate bottom electrodes to enable the separate programming of the two phase change cells. Each memristive device uses an access device, such as a high-current-delivering transistor. In fact, because the programming currents are relatively large, each memristive device may use two access devices to support the relatively large programming currents. Thus, having two access devices may be useful when two memristive devices represent one compute unit cell via their connection to the common bit line (e.g., the shared top electrode). For example, using two access devices may improve the signal to noise ratio due to the larger current accumulation. Further, using two access devices per memristive device can provide an averaging of the temporal fluctuations between the two access devices. Additionally, the two access devices may be useful in cases involving positive and negative weights. In such cases, two access devices may make it possible to individually program the positive and negative weights. However, the scenarios described above may cause areal inefficiencies by using multiple access devices for each memristive device. In other words, the device density (e.g., the number of devices) per unit area decreases due to having multiple access devices. As such, it may be useful to have a compute unit cell design which may decrease the programming currents of the memristive device, thus reducing the number of access devices used and increasing the device density. Further, having multiple memristive devices in a single compute unit cell can lead to thermal crosstalk between the memristive devices. This thermal crosstalk may result from the limited ability to reduce thermal energy in the compute unit cell due to the limited area for providing a heat sink in the shared region of the memristive devices.

Accordingly, some embodiments of the present disclosure may include a memristive device with an edge bottom electrode and vertical current flow device geometry. The device may provide access to two or more memristive devices and reduce the programming currents in each cell. Additionally, such embodiments enable multiple devices to be programmed and read, either in parallel or separately. Programming and reading in parallel may improve compute precision. Further, programing and reading separately may allow for a differential pair to be mapped into a unit cell. In these ways, such embodiments can reduce the number of access transistors, thus providing savings on the areal footprint. Additionally, such embodiments may reduce the programming currents, and the amount of crosstalk between the memristive devices. Further, such embodiments may be useful for projected devices, non-projected devices, and memristive devices, including resistive memories. Accordingly, such embodiments can improve the operation of computer technology. However, some embodiments of the present disclosure may not achieve such advantages.

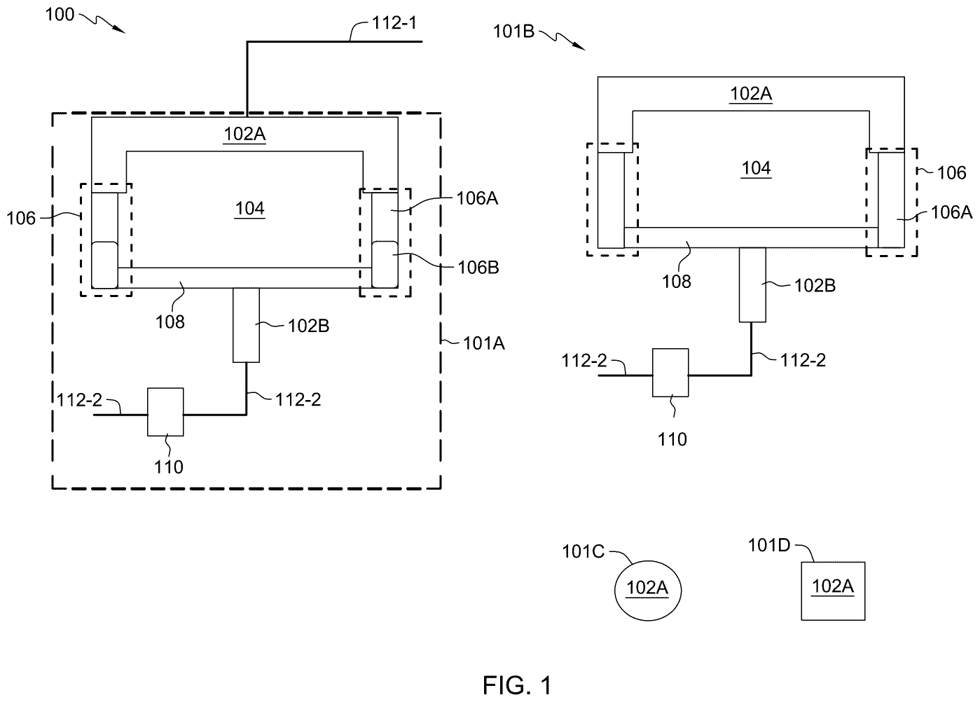

FIG. 1 depicts example non-volatile memory unit cells 101A, 101B, 101C, and 101D, (collectively referred to as memory unit cells 101) having edge-contacted memristive channels 106, in accordance with some embodiments of the present disclosure. The non-volatile memory unit cells 101A and 101B depict example internal cross-sectional views. The non-volatile memory unit cells 101C and 101D represent example top views. FIG. 1 depicts the example non-volatile memory unit cells 101 with a bit line 112-1, and a select line 112-2. The example non-volatile memory unit cells 101 (also referred to herein as, memristive device) includes a top electrode 102A, bottom electrode 102B, dielectric 104, memristive channels 106, thin film electrode 108, and an access device 110. The top electrode 102A and bottom electrode 102B are made from electrically conductive materials, in contact with the bit line 112-1 and select line 112-2, respectively. Further, the select line 112-2 may be connected to the access device 110. The access device 110 may be a field effect transistor (FET), bipolar junction transistor, nonlinear selector, pn junction, Schottky diode, and the like. A layer of phase change material may surround the dielectric 104 and thin film electrode 108. A portion of this phase change material is represented by the memristive channels 106. The memristive channels 106 may be paths through a phase change material that current follows when the bit line 112-1 is accessed. Accordingly, the electric current may change the phase of a portion of each of the memristive channels 106 from crystalline to amorphous (and vice-versa). In this way, the non-volatile memory unit cell 101 may program multiple memristive channels 106 in parallel.

Further, the top electrode 102A and thin film electrode 108 are each in edge contact with the memristive channels 106. The select line 112-2 provides current to the access device 110, which may be a transistor, such as a field effect transistor (FET), stacked FET, and the like. The current may flow through the bottom electrode 102B, the thin film electrode 108, the memristive channels 106, the top electrode 102A, and the bit line 112-1.

Accordingly, the access device 110 may provide programming current (e.g., electrical write pulses) to the example non-volatile memory unit cell 101. As state previously, each of the memristive channels 106 may be composed of phase change material. Accordingly, applying the write electrical pulses from the select line 112-2 to the phase change material may provide the energy to change a portion of the phase change material from a crystalline state to an amorphous state. In other words, portions of the phase change material of the memristive channels 106 may become amorphous phase change material 106B after a write operation. In this example, the memristive channels 106 include a crystalline phase change material 106A and an amorphous phase change material 106B. As the example non-volatile memory unit cell enables parallel programming of the memristive channels 106, the composition of crystalline phase change material 106A and amorphous phase change material 106B is the same in both memristive channels 106. The thinner the phase change materials are, the more efficient the non-volatile memory unit cell 101 is. Additionally, while two memristive channels 106 are shown in this example, in some embodiments of the present disclosure, the non-volatile memory unit cell 101 may include more than two memristive channels 106.

Similar to the top electrode 102A, the bottom electrode 102B may allow electric current to pass from the thin film electrode 108 to the select line 112-2. Additionally, the bottom electrode 102B may act as a heat sink for the non-volatile memory unit cell 101, thus reducing the crosstalk between the memristive channels 106.

The dielectric 104 may be an oxide, such as, silicon oxide, a nitride, such as, silicon nitride, and the like. The dielectric 104 may provide isolation between the top electrode 102A, thin film electrode 108, and memristive channels 106. The dielectric 104 can be deposited in a blanket layer using any known deposition techniques, such as, for example, chemical vapor deposition, atomic layer deposition, physical layer deposition, or some combination thereof. More specifically, the dielectric 104 may be deposited within and generally fill the spaces between the thin film electrode 108, the memristive channels 106 and the top electrode 102A.

As stated previously, when the phase change memory cell is in use, the phase change material may be operated in one of at least two reversibly transformable phases, an amorphous phase and a crystalline phase. Phase change material may comprise one of GeSbTe, VOx, NbOx, GeTe, GeSb, GaSb, AgInSbTe, InSb, InSbTe, InSe, SbTe, TeGeSbS, AgSbSe, SbSe, GeSbMnSn, AgSbTe, AuSbTe, AlSb, and the like.

According to some embodiments of the present disclosure, the thin film electrode 108 may be a thin non-insulating material composed of a conductive thin film, with an edge contact to the memristive channels 106. This edge contacted design allows energy efficient programming. Additionally, the example non-volatile memory unit cell 101 may include a thin film of side-wall phase change film (not shown) for switching layer confinement. Accordingly, this feature may provide a reduction in the programming current passing from the phase change material 106B through the thin film electrode 108 to the bottom electrode 102B. Further, the reduction of programming currents can also enable access to the example non-volatile memory unit cell 101 with one access device, e.g., access device 110.

Alternatively, in current systems, a pair of compute unit cells can be used with a differential pair, where positive and negative weights are provided through distinct bit lines. Each of the bit lines for the positive and negative weights may be connected with two memristive devices within one compute unit cell. As such, in a typical configuration, there may be 8 transistors and four phase change material cells in a conventional compute unit cell system using a differential pair. However, the many elements involved in a differential pair further decrease the device density. Accordingly, in some embodiments of the present disclosure, a compute unit cell having memristive devices may be deployed in a differential pair.

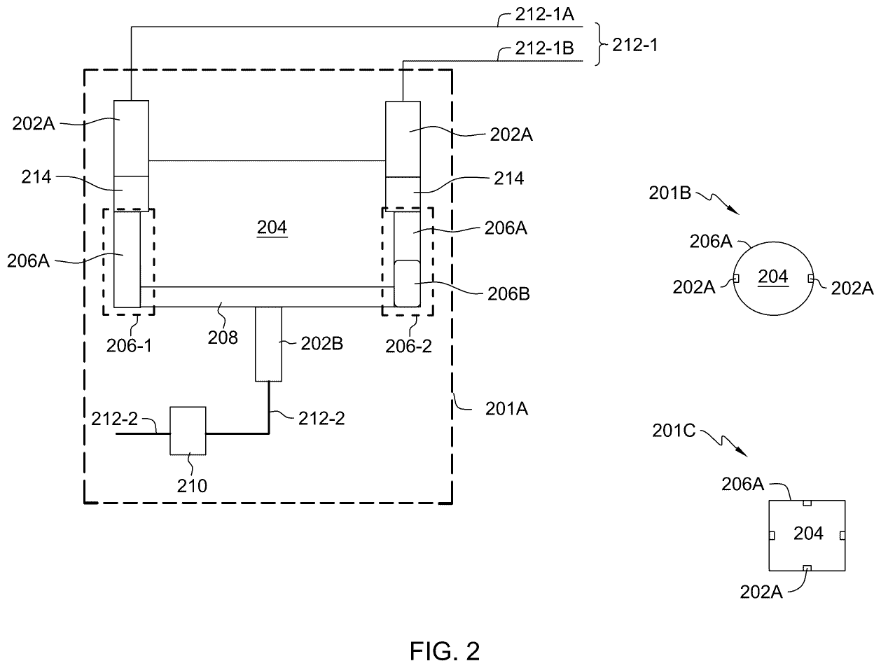

FIG. 2 depicts example non-volatile memory unit cells 201A, 201B, 201C (collectively referred to herein as non-volatile memory unit cells 201) having edge-contacted memristive channels 206-1, 206-2 (collectively referred to as memristive channels 206) and a differential pair 212-1, in accordance with some embodiments of the present disclosure. Non-volatile memory unit cell 201A is depicted using an internal cross-sectional view. The non-volatile memory unit cells 201B, 201C represent different top views of the non-volatile memory unit cell 201A. FIG. 2 depicts the example non-volatile memory unit cells 201, the differential pair 212-1 (consisting of bit lines 212-1A, 212-1B), a select line 212-2, and an access device 210. The select line 212-2 may be similar to the select line 112-2, and the access device 210 may be similar to the access device 110, both described with respect to FIG. 1.

However, in contrast to the parallel programming of the memristive channels 106 of FIG. 1, the differential pair 212-1 may enable programming current to individually program memristive channels 206-1, 206-2 in response to a programming operation. For example, during a write operation, one of the bit lines 212-1A, 212-1B can be disabled in order to individually program the memristive channel 206 on the counterpart bit line. In this example, the result of such an operation is shown. More specifically, the bit line 212-1A was disabled to enable individually programming memristive channel 206-2, which as a result, includes crystalline phase change material 206A and amorphous phase change material 206B. In contrast, the memristive channel 206-1 of the disabled bit line 212-1A merely includes the unchanged crystalline phase change material 206A.

Similarly, during a read operation, one of the bit lines can be disabled to enable reading the memristive channel on the counterpart bit line. Additionally, during read out, both bit lines 212-1A, 212-1B can be enabled, such that a voltage applied on the select line 212-2 (transistor source), is dropped on both memristive channels 206. In other words, both memristive channels 206-1, 206-2 produce independent currents due to the parallel configuration.

Further, the example non-volatile memory unit cells 201 include two top electrodes 202A. Thus, the two distinct bit lines 212-1A, 212-1B can be additionally separated by making connections to the two distinct top electrodes 202A of the non-volatile memory unit cells 201. As such, one access device, e.g., access device 210 can be used to access both the memristive channels 206-1, 206-2. Alternatively, in some embodiments, there may be more than one access device 210. More specifically, the number of access devices 210 may scale with the programming currents used to program the memristive channels 206.

Additionally, the example non-volatile memory unit cells 201 include bottom electrode 202B, dielectric 204, memristive channels 206-1, 206-2 (collectively referred to as memristive channels 206), thin film electrode 208, and thin film diodes 214. The bottom electrode 202B, memristive channels 206, and thin film electrode 208 may be respectively similar to the bottom electrode 102B, memristive channels 106, and thin film electrode 108, described with respect to FIG. 1. The thin film diodes 214 may be non-linear rectifying elements that can control which of the memristive channels 206 that current is allowed to pass through. As such, the thin film diodes 214 may provide a rectification in current flow direction. This may reduce sneak path currents between the memristive channels 206.

During programming, one bit line is kept floating (electrically open) so that the current flows through the other bit line. For example, bit line 212-1A may be kept floating so that current flows through bit line 212-1B. Further, during a read operation, both bit lines 212-1A, 212-1B can accumulate currents. For example, to map the value, “b” to a PCM cell, the “b” value may be programmed to either memristive channel 206-1 or memristive channel 206-2. When programming on memristive channel 206-1, the value can be programmed as a positive number. Alternatively, when programming on memristive channel 206-2, the value can be programmed as a negative number.

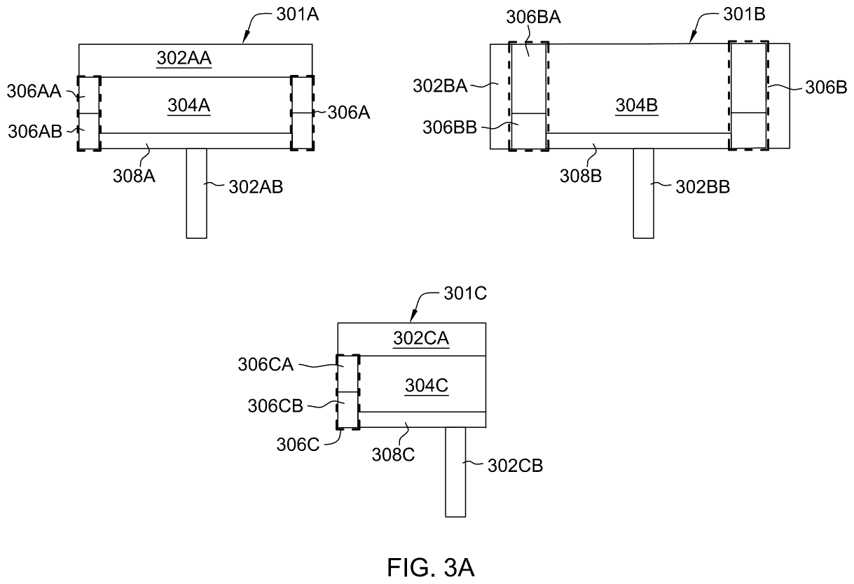

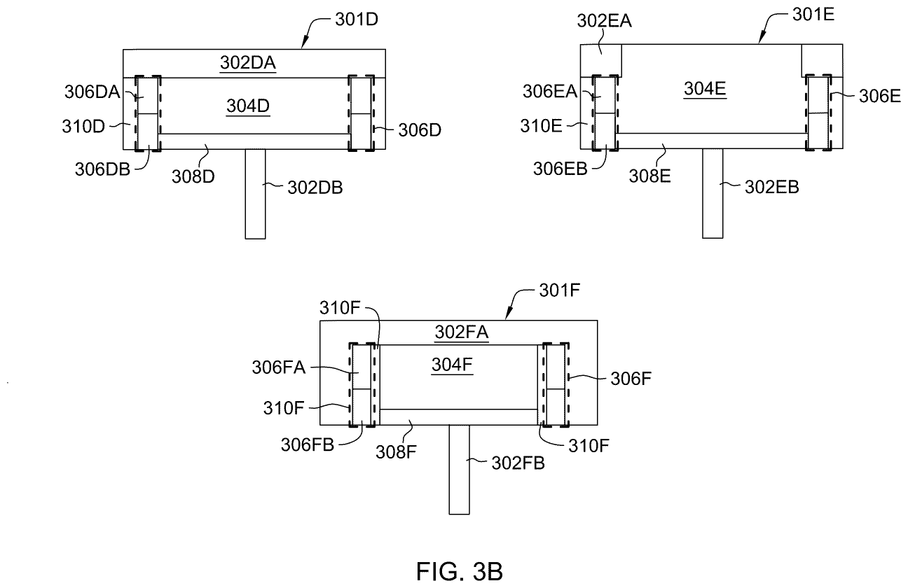

FIG. 3A is internal cross-sectional views of example memristive devices having edge-contacted memristive devices, in accordance with some embodiments of the present disclosure. The example memristive devices include memristive devices 301A, 301B, 301C. The memristive device 301A includes a top electrode 302AA, bottom electrode 302AB, dielectric 304A, memristive channels 306A (having crystalline phase change material 306AA and amorphous phase change material 306AB), and thin film electrode 308A, which are respectively similar to the top electrode 102A, bottom electrode 102B, dielectric 104, memristive channels 106, and thin film electrode 108, described with respect to FIG. 1.

The memristive device 301B includes two edge electrodes 302BA, bottom electrode 302BB, dielectric 304B, memristive channels 306B (having crystalline phase change material 306BA and amorphous phase change material 306BB), and thin film electrode 308B. The edge electrodes 302BA, bottom electrode 302BB, dielectric 304B, crystalline phase change material 306BA, amorphous phase change material 306BB, and thin film electrode 308B are respectively similar to the top electrodes 202A, bottom electrode 202B, dielectric 204, crystalline phase change material 206A, amorphous phase change material 206B, and thin film electrode 208, described with respect to FIG. 2. However, in contrast to the top electrodes 202A, the edge electrodes 302BA are located at the edges of the crystalline phase change materials 306BA and amorphous change materials 306BB (i.e., memristive devices).

The memristive device 301C includes a top electrode 302CA, bottom electrode 302CB, dielectric 304C, memristive channels 306C (having crystalline phase change material 306CA and amorphous phase change material 306CB), and thin film electrode 308C. The top electrode 302CA, bottom electrode 302CB, dielectric 304C, memristive channels 306C and thin film electrode 308C are respectively similar to the top electrode 302A, bottom electrode 302AB, dielectric 304A, memristive channels 306A, and thin film electrode 308A, described with respect to memristive device 301A. However, in contrast to memristive device 301A, memristive device 301C contains one memristive channel.

In memristive devices 301A and 301C, current flows vertically from the thin film electrode 308A, 308C to the top electrode 302AA, 302CA. Conversely, in memristive device 301B, current flows horizontally from the thin film electrode 308B to the top electrode 302BA.

FIG. 3B is internal cross-sectional views of example memristive devices having projected-type, edge-contacted memristive devices, in accordance with some embodiments of the present disclosure. The example memristive devices include memristive devices 301D, 301E, 301F. The memristive device 301D includes a top electrode 302DA, bottom electrode 302DB, dielectric 304D, memristive channels 306D (having crystalline phase change material 306DA and amorphous phase change material 306DB), thin film electrode 308D, and projection layers 310D. The top electrode 302DA, bottom electrode 302DB, dielectric 304D, memristive channels 306D, and thin film electrode 308D are respectively similar to the top electrode 302AA, bottom electrode 302AB, dielectric 304A, memristive channels 306A, and thin film electrode 308A, described with respect to FIG. 3A.

The projection layers 310D are non-insulating thin film layers that re-direct current flow from a phase change layer segment (e.g., phase change material 306DB) that is amorphous. Because the projection layers 310D have less resistance than the amorphous phase change material 306DB, when the amorphous phase change material 306DB is programmed, the programming current will flow from the amorphous phase change material 306DB to the projection layers 310D, and from the projection layers 310D to the crystalline phase change material 306DA. Further, the amorphous phase change material 306DB may be unstable (e.g., changing) over time. However, in contrast the projection layers 310D are more stable than the amorphous phase change material 306DB. As such, the current flows in the liner layer of the projection layer 310D, thus bypassing the amorphous phase change material 306DB.

The memristive device 301E includes two top electrodes 302EA, bottom electrode 302EB, dielectric 304E, memristive channels 306E (having crystalline phase change material 306EA and amorphous phase change material 306EB), and thin film electrode 308E. The top electrodes 302EA, bottom electrode 302EB, dielectric 304E, memristive channels 306E, and thin film electrode 308E are respectively similar to the top electrodes 302BA, bottom electrode 302BB, dielectric 304B, memristive channels 306B, and thin film electrode 308B, described with respect to memristive device 301B of FIG. 3A. However, in contrast to memristive device 301B, the memristive device 301E additionally includes projection layers 310E, which are similar to the projection layers 310D. Additionally, the dielectric 304E is coplanar with the top electrodes 302EA.

The memristive device 301F includes a top electrode 302FA, bottom electrode 302FB, dielectric 304F, crystalline phase change material 306FA, amorphous phase change material 306FB, and thin film electrode 308F. The top electrode 302FA, bottom electrode 302FB, dielectric 304F, crystalline phase change material 306FA, memristive channels 306F (having amorphous phase change material 306FB), and thin film electrode 308F are respectively similar to the top electrode 302CA, bottom electrode 302CB, dielectric 304C, crystalline phase change material 306CA, amorphous phase change material 306CB, and thin film electrode 308C, described with respect to memristive device 301C of FIG. 3A. However, in contrast to memristive device 301C, the memristive device 301F additionally includes projection layers 310F, which are similar to the projection layers 310E.

In memristive device 301F, the current flows horizontally. Conversely, in memristive devices 301E, the flow is vertical to the top electrode 302EA.

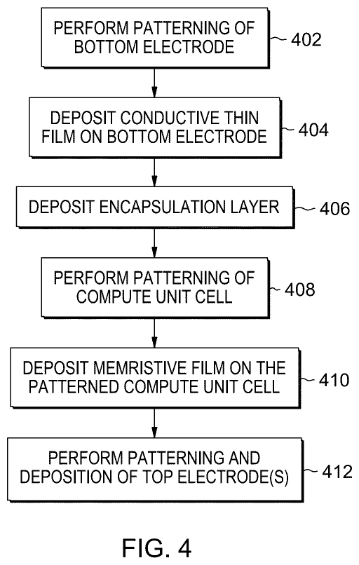

FIG. 4 is a process flow chart of a method for fabricating a non-volatile memory unit cell having memristive devices with shared electrodes, in accordance with some embodiments of the present disclosure. The method may be performed by semiconductor fabrication devices.

At operation 402, a fabrication device may perform patterning of a bottom electrode. The bottom electrode may be similar to the bottom electrodes 102B, 202B, described with respect to FIGS. 1 and 2.

At operation 404, a fabrication device may deposit a conductive thin film comprising a thin film electrode on the bottom electrode. The thin film electrode may be similar to the thin film electrodes 108, 208, described with respect to FIGS. 1 and 2.

At operation 406, a fabrication device may deposit an encapsulation layer (e.g., dielectric 104). The dielectric may be deposited on the thin film electrode.

At operation 408, a fabrication device may perform patterning of the compute unit cell. Patterning of the non-volatile memory unit cell may create trenches for depositing a memristive film (e.g., phase change materials).

At operation 410, a fabrication device may deposit a memristive film on the patterned non-volatile memory unit cell. The memristive film may comprise phase change materials.

At operation 412, a fabrication device may perform patterning, and deposition, of one or more top electrodes. The top electrodes may be similar to the top electrodes 102A, 202A.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks. When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category. For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations. Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A non-volatile memory unit cell, comprising:
a top electrode in contact with a bit line;
a bottom electrode in contact with a select line;
a thin film electrode in contact with the bottom electrode;
a dielectric in contact with the top electrode and the thin film electrode; and
a layer of phase change material comprising a plurality of memristive channels, wherein the layer of phase change material is in contact with the dielectric, and wherein the plurality of memristive channels are in contact with:
the top electrode,
the thin film electrode, and
the dielectric.

2. The non-volatile memory unit cell of claim 1, wherein the plurality of memristive channels are in edge contact with the thin film electrode.

3. The non-volatile memory unit cell of claim 1, wherein each of the plurality of memristive channels comprises a portion of the layer of phase change material.

4. The non-volatile memory unit cell of claim 1, further comprising an access device, wherein the select line is in contact with the access device.

5. The non-volatile memory unit cell of claim 4, wherein the access device comprises a field effect transistor.

6. The non-volatile memory unit cell of claim 1, wherein the top electrode comprises an edge electrode.

7. The non-volatile memory unit cell of claim 1, further comprising a projection layer in contact with the layer of phase change material.

8. The non-volatile memory unit cell of claim 1, wherein the non-volatile memory unit cell is configured to enable electric current to flow horizontally between the thin film electrode and the memristive channel.

9. The non-volatile memory unit cell of claim 1, wherein the non-volatile memory unit cell is configured to enable electric current to flow vertically from the bottom electrode to the top electrode, and through the thin film electrode and the memristive channel.

10. A non-volatile memory unit cell, comprising:
a first top electrode in contact with a first bit line;
a second top electrode in contact with a second bit line, wherein a differential pair comprises the first bit line and the second bit line;
a first diode in contact with the first top electrode;
a second diode in contact with the second top electrode;
a bottom electrode in contact with a select line;
a thin film electrode in contact with the bottom electrode;
a dielectric in contact with the first top electrode, the second top electrode, the first diode, the second diode, and the thin film electrode;
a layer of phase change material comprising a first memristive channel and a second memristive channel, wherein the layer of phase change material is in contact with the dielectric, and wherein the first memristive channel is in contact with:
the thin film electrode,
the first diode, and
the dielectric; and
wherein the second memristive channel is in contact with:
the thin film electrode,
the second diode, and
the dielectric.

11. The non-volatile memory unit cell of claim 10, wherein the first memristive channel and the second memristive channel are in edge contact with the thin film electrode.

12. The non-volatile memory unit cell of claim 10, wherein the select line is in contact with an access device.

13. The non-volatile memory unit cell of claim 10, further comprising an access device, wherein the select line is in contact with the access device.

14. The non-volatile memory unit cell of claim 10, wherein each of the first top electrode and the second top electrode comprises an edge electrode.

15. The non-volatile memory unit cell of claim 10, further comprising a projection layer in contact with the layer of phase change material.

16. The non-volatile memory unit cell of claim 10, wherein the dielectric is coplanar with the first top electrode and the second top electrode.

17. The non-volatile memory unit cell of claim 10, wherein the non-volatile memory unit is configured to enable electric current to flow horizontally between the thin film electrode and: the first memristive channel and the second memristive channel.

18. A method for fabricating a semiconductor structure, the method comprising:
performing patterning of a bottom electrode;
depositing a conductive thin film on the bottom electrode;
depositing a dielectric layer on the conductive thin film;
performing patterning of a non-volatile memory unit cell;
depositing a memristive film on the patterned non-volatile memory unit cell;
performing patterning of a first top electrode; and
depositing the top electrode on the memristive film.

19. The method of claim 18, wherein the memristive film comprises a first memristive film and a second memristive film, and wherein depositing the memristive film comprises:
depositing the first memristive film on a first edge of the patterned non-volatile memory unit cell; and
depositing the second memristive film on a second edge of the patterned non-volatile memory unit cell.

20. The method of claim 19, further comprising performing patterning of a second top electrode; and
depositing the second top electrode on the second memristive film.
